(19) United States
(12) Patent Application Publication
(10) Pub. No.: US 2019/0305788 A1
(43) Pub. Date: Oct. 3, 2019

(54) SEMICONDUCTOR LASER, ATOMIC OSCILLATOR, AND FREQUENCY SIGNAL GENERATION SYSTEM

(71) Applicant: Seiko Epson Corporation, Tokyo (JP)

(72) Inventor: Junichi OKAMOTO, Shiojiri (JP)

(21) Appl. No.: 16/364,291

(22) Filed: Mar. 26, 2019

(30) Foreign Application Priority Data
Mar. 27, 2018 (JP) 2018-060605

(51) Int. Cl. H03L 7/26; H01S 5/026; G04F 5/14; H01S 5/183; H01S 5/042; H01S 5/06

(52) U.S. Cl. CPC H03L 7/26; H01S 5/0261; H01S 5/0612; H01S 5/18377; H01S 5/0425; G04F 5/145

(57) ABSTRACT

A semiconductor laser includes a first mirror layer, a second mirror layer, an active layer disposed between the first mirror layer and the second mirror layer, a semiconductor layer disposed in the second mirror layer, an insulation region configured to insulate the second mirror layer and the semiconductor layer from each other, a first electrode connected to the first mirror layer, a second electrode connected to the second mirror layer, and a third electrode connected to the semiconductor layer.

### CROSS-REFERENCE TO RELATED APPLICATIONS

This application claims priority to Japanese Patent Application No. 2018-060605, filed Mar. 27, 2018, the entirety of which is hereby incorporated by reference.

### BACKGROUND

### 1. Technical Field

The present invention relates to a semiconductor laser, an atomic oscillator, and a frequency signal generation system.

### 2. Related Art

In recent years, an atomic oscillator using coherent population trapping (CPT) as one kind of a quantum interference effect is proposed. The atomic oscillator using CPT is an oscillator using an electromagnetically-induced transparency (EIT) phenomenon in which absorption of coherent light is stopped if an alkali metal atom is irradiated with the coherent light having two kinds of wavelengths (frequencies). It is necessary that the wavelength of light emitted from a light source is controlled with high accuracy, in the atomic oscillator using CPT.

A semiconductor laser used as a light source of the atomic oscillator has an oscillation wavelength which fluctuates by temperature fluctuation. Therefore, for example, in an atomic oscillator disclosed in JP-A-2015-119152, temperature fluctuation of a light emitting element is reduced in a manner that a wiring layer on a relay member having a temperature adjusted by a temperature adjustment surface is interposed in the middle of a wiring connecting the light emitting element and an external terminal to each other, so as to reduce temperature fluctuation of the wiring.

As in the atomic oscillator disclosed in JP-A-2015-119152, in a case where the semiconductor laser is used as the light source, it is possible to control the oscillation wavelength by a drive current. However, if the drive current is changed in order to control the oscillation wavelength of the semiconductor laser, a light output of the semiconductor laser is also changed. The change of the light output of the semiconductor laser may cause a light shift, and thus deteriorate frequency stability of the atomic oscillator.

### SUMMARY

An aspect of a semiconductor laser according to the invention includes a first mirror layer, a second mirror layer, an active layer disposed between the first mirror layer and the second mirror layer, a semiconductor layer disposed in the second mirror layer, an insulation region configured to insulate the second mirror layer and the semiconductor layer from each other, a first electrode connected to the first mirror layer, a second electrode connected to the second mirror layer, and a third electrode connected to the semiconductor layer.

The aspect of the semiconductor laser may further include a substrate. The second mirror layer may be disposed on an opposite side of the substrate with respect to the active layer.

The aspect of the semiconductor laser may further include an insulation layer having an opening. The insulation region may not overlap the opening viewed in a plan view of the second mirror layer.

In the aspect of the semiconductor laser, the semiconductor layer may have a first portion in-plane with the second mirror layer, and a second portion that overlaps the first portion in a plan view of the second mirror layer. A sectional area of the second portion along the first portion may be larger than a sectional area of the first portion along the second portion.

In the aspect of the semiconductor laser, the second electrode may be connected to the semiconductor layer.

An aspect of an atomic oscillator according to the invention includes a semiconductor laser, an atomic cell which is irradiated with light emitted from the semiconductor laser and in which an alkali metal atom is accommodated, and a light receiving element that detects intensity of light transmitted through the atomic cell and outputs a detection signal. The semiconductor laser includes a first mirror layer, a second mirror layer, an active layer disposed between the first mirror layer and the second mirror layer, a semiconductor layer disposed in the second mirror layer, an insulation region configured to insulate the second mirror layer and the semiconductor layer from each other, a first electrode connected to the first mirror layer, a second electrode connected to the second mirror layer, and a third electrode connected to the semiconductor layer.

The aspect of the atomic oscillator may further include a light-output control circuit that controls a light output of the semiconductor laser by supplying a current to the first electrode and the second electrode of the semiconductor laser based on the detection signal, and a wavelength control circuit that controls an oscillation wavelength of the semiconductor laser by supplying a current to the third electrode based on the detection signal.

An aspect of a frequency signal generation system according to the invention includes an atomic oscillator. The atomic oscillator includes a semiconductor laser, an atomic cell which is irradiated with light emitted from the semiconductor laser, and in which an alkali metal atom is accommodated, and a light receiving element that detects intensity of light transmitted through the atomic cell and outputs a detection signal. The semiconductor laser includes a first mirror layer, a second mirror layer, an active layer disposed between the first mirror layer and the second mirror layer, a semiconductor layer disposed in the second mirror layer, an insulation region configured to insulate the second mirror layer and the semiconductor layer from each other, a first electrode connected to the first mirror layer, a second electrode connected to the second mirror layer, and a third electrode connected to the semiconductor layer.

### BRIEF DESCRIPTION OF THE DRAWINGS

The embodiments will be described with reference to the accompanying drawings, wherein like numbers reference like elements.

FIG. 1 is a functional block diagram illustrating an atomic oscillator according to an embodiment.

FIG. 2 is a diagram illustrating an energy state of an alkali metal atom in an atomic cell.

FIG. 3 is a graph illustrating a relation between a frequency difference between two kinds of light emitted from a semiconductor laser and detection intensity detected by a light receiving element.

FIG. 4 is a perspective view schematically illustrating a light-emitting device module.

FIG. 5 is a plan view schematically illustrating the light-emitting device module.

FIG. 6 is a sectional view schematically illustrating the light-emitting device module.

FIG. 7 is a sectional view schematically illustrating the semiconductor laser.

FIG. 8 is a plan view schematically illustrating the semiconductor laser.

FIG. 9 is a perspective view schematically illustrating a heater element.

FIG. 10 is a sectional view schematically illustrating a step of manufacturing the semiconductor laser, according to the embodiment.

FIG. 11 is a sectional view schematically illustrating the step of manufacturing the semiconductor laser, according to the embodiment.

FIG. 12 is a sectional view schematically illustrating the step of manufacturing the semiconductor laser, according to the embodiment.

FIG. 13 is a sectional view schematically illustrating the step of manufacturing the semiconductor laser, according to the embodiment.

FIG. 14 is a sectional view schematically illustrating the step of manufacturing the semiconductor laser, according to the embodiment.

FIG. 15 is a perspective view schematically illustrating a heater element of a semiconductor laser according to a first modification example.

FIG. 16 is a plan view schematically illustrating a semiconductor laser according to a second modification example.

FIG. 17 is a perspective view schematically illustrating a heater element of the semiconductor laser according to the second modification example.

FIG. 18 is a plan view schematically illustrating a semiconductor laser according to a third modification example.

FIG. 19 is a diagram illustrating an example of a frequency signal generation system according to the embodiment.

### DESCRIPTION OF EXEMPLARY EMBODIMENTS

Hereinafter, the preferred embodiments will be described in detail with reference to the drawings. The embodiment described below does not unduly limit the contents of the invention described in the appended claims. Not all configurations described below are necessarily essential components of the invention.

### 1. Atomic Oscillator

### 1.1. Configuration of Atomic Oscillator

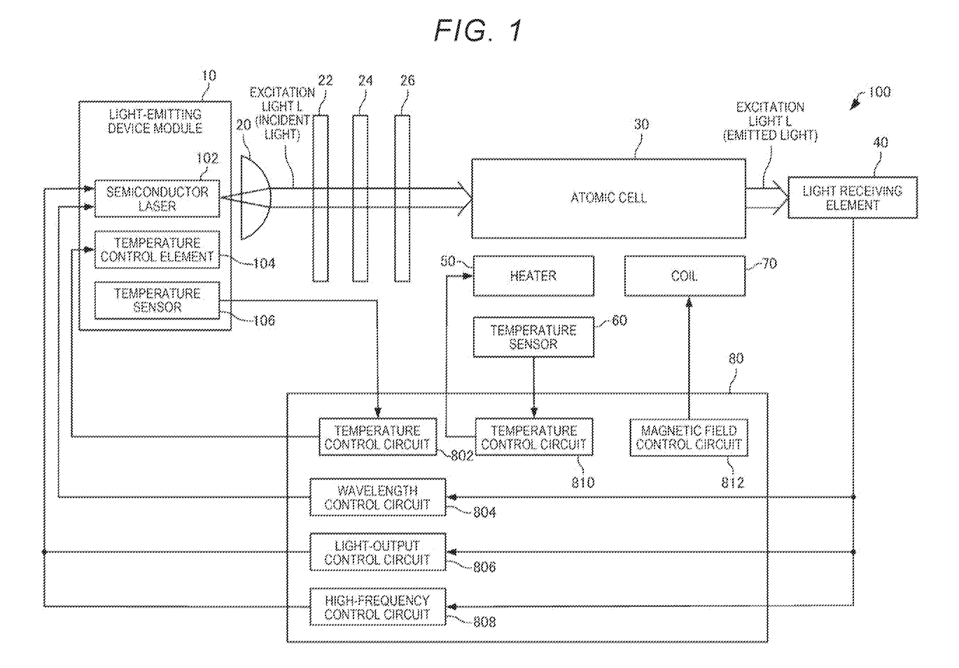

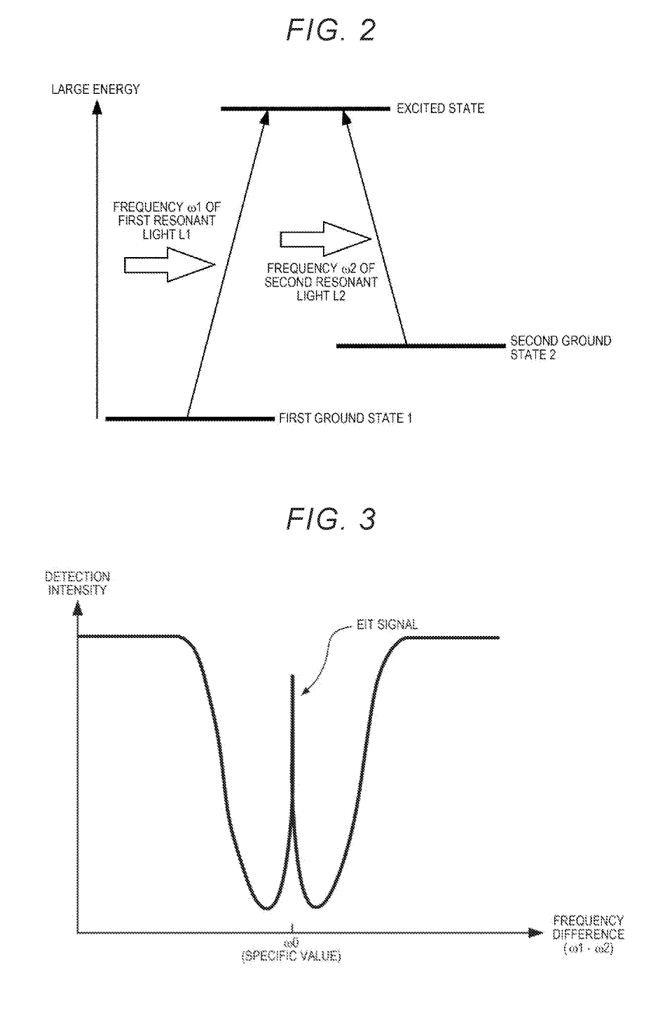

Firstly, a configuration of an atomic oscillator according to an embodiment will be described with reference to the drawings. FIG. 1 is a functional block diagram illustrating an atomic oscillator 100 according to the embodiment. FIG. 2 is a diagram illustrating an energy state of an alkali metal atom in an atomic cell 30 of the atomic oscillator 100 according to the embodiment. FIG. 3 is a graph illustrating a relation between a frequency difference and detection intensity in the atomic oscillator 100 according to the embodiment. The frequency difference refers to a frequency difference between two kinds of light emitted from a semiconductor laser 102. The detection intensity is detected by a light receiving element 40.

The atomic oscillator 100 uses the quantum interference effect. The atomic oscillator 100 using the quantum interference effect can have a reduced size in comparison to an atomic oscillator using the double resonance effect.

The atomic oscillator 100 includes a semiconductor laser. Here, a case in which the atomic oscillator 100 includes the semiconductor laser 102 will be described. As illustrated in FIG. 1, the atomic oscillator 100 includes a light-emitting device module 10, optical members 20, 22, 24, and 26, an atomic cell 30, a light receiving element 40, a heater 50, a temperature sensor 60, a coil 70, and a controller 80.

Firstly, the principle of the atomic oscillator 100 will be described.

In the atomic oscillator 100, gaseous alkali metal atoms of rubidium, cesium, sodium, and the like are sealed in the atomic cell 30.

As illustrated in FIG. 2, the alkali metal atom has an energy level of a three-level system. The alkali metal atom maybe in three states of two ground states (first ground state 1 and second ground state 2) and an excited state. The two ground states have different energy levels. Here, the first ground state 1 is lower than the second ground state 2.

If the gaseous alkali metal atom is irradiated with first resonant light L1 and second resonant light L2 having frequencies different from each other, light absorption rates (light transmittance) of the first resonant light L1 and the second resonant light L2 in the alkali metal atom change depending on a difference (ω1−ω2) between the frequency ω1 of the first resonant light L1 and the frequency ω2 of the second resonant light L2. When the difference (ω1−ω2) between the frequency ω1 of the first resonant light L1 and the frequency ω2 of the second resonant light L2 matches with a frequency corresponding to an energy difference between the first ground state 1 and the second ground state 2, excitation from the ground states 1 and 2 to the excited state is stopped. At this time, neither the first resonant light L1 nor the second resonant light L2 is not absorbed but transmitted through the alkali metal atom. Such a phenomenon is referred to as a CPT phenomenon or an electromagnetically-induced transparency (EIT) phenomenon.

Here, for example, if the frequency ω1 of the first resonant light L1 is fixed, and the frequency ω2 of the second resonant light L2 is changed, detection intensity of the light receiving element 40 rapidly increases, as illustrated in FIG. 3, when the difference (ω1−ω2) between the frequency ω1 of the first resonant light L1 and the frequency ω2 of the second resonant light L2 matches with a frequency ω0 corresponding to an energy difference between the first ground state 1 and the second ground state 2. Such a steep signal is referred to as an EIT signal. The EIT signal has a fixed value which has been determined in accordance with the type of alkali metal atom. Thus, it is possible to realize an oscillator having high accuracy by using the EIT signal as a reference.

Components of the atomic oscillator 100 will be described below.

### Light-Emitting Device Module

As illustrated in FIG. 1, the light-emitting device module 10 emits excitation light L causing the alkali metal atom in the atomic cell 30 to be excited. Specifically, the light-emitting device module 10 emits the first resonant light L1 and the second resonant light L2 as the excitation light L.

As illustrated in FIG. 2, the first resonant light L1 causes the alkali metal atom in the atomic cell 30 to be excited from the first ground state 1 to the excited state. The second resonant light L2 causes the alkali metal atom in the atomic cell 30 to be excited from the second ground state 2 to the excited state.

As illustrated in FIG. 1, the light-emitting device module 10 includes the semiconductor laser 102, a temperature control element 104, and a temperature sensor 106. Details of the light-emitting device module 10 will be described later.

### Optical Member

The optical members 20, 22, 24, and 26 are provided on an optical path of the excitation light L between the light-emitting device module 10 and the atomic cell 30. In the example illustrated in FIG. 1, the first optical member 20, the second optical member 22, the third optical member 24, and the fourth optical member 26 are disposed from the light-emitting device module 10 side toward the atomic cell 30 side in this order.

The first optical member 20 is a lens that makes the excitation light L into parallel light. The second optical member 22 is a polarizing plate that aligns polarized light of the excitation light L from the light-emitting device module 10, in a predetermined direction. The third optical member 24 is a dimming filter that reduces intensity of the excitation light L incident to the atomic cell 30, that is, a neutral density filter (ND filter). The fourth optical member 26 is a λ/4 wave plate. The fourth optical member 26 transforms the excitation light L from the light-emitting device module 10, from linearly-polarized light into circularly-polarized light.

### Atomic Cell

The atomic cell 30 is irradiated with the excitation light L emitted from the semiconductor laser 102. In the example in FIG. 1, the atomic cell 30 is irradiated with the excitation light L emitted from the semiconductor laser 102 of the light-emitting device module 10 through the optical members 20, 22, 24, and 26. The gaseous alkali metal atoms are accommodated in the atomic cell 30. If necessary, a rare gas such as argon or neon, an inert gas such as nitrogen may be accommodated as a buffer gas in the atomic cell 30, along with the gaseous alkali metal atom.

### Light Receiving Element

The light receiving element 40 detects the intensity of the excitation light L (first resonant light L1 and second resonant light L2) transmitted through the atomic cell 30 and outputs a detection signal depending on the intensity of the light. For example, a photodiode may be used as the light receiving element 40.

### Heater

The heater 50 heats the atomic cell 30, more specifically, the alkali metal atoms accommodated in the atomic cell 30. Thus, it is possible to maintain the alkali metal atom in the atomic cell 30 to be in a gaseous state having appropriate density. The heater 50 includes, for example, a heating resistor that is energized so as to generate heat.

### Temperature Sensor

The temperature sensor 60 measures the temperature of the heater 50 or the atomic cell 30. The quantity of heat generated by the heater 50 is controlled based on a measurement result of the temperature sensor 60. Thus, it is possible to maintain the temperature of the alkali metal atom in the atomic cell 30 to be a desired temperature. For example, well-known temperature sensors such as a thermistor and a thermocouple may be used as the temperature sensor 60.

### Coil

The coil 70 generates a magnetic field that Zeeman-splits a plurality of degenerate energy levels of the alkali metal atom in the atomic cell 30. With the Zeeman splitting, the coil 70 can expand a gap between the degenerate different energy levels of the alkali metal atom so as to improve a resolution. As a result, it is possible to improve accuracy of an oscillation frequency of the atomic oscillator 100.

For example, the coil 70 is a Helmholtz coil disposed so as to sandwich the atomic cell 30, or a solenoid coil disposed so as to cover the atomic cell 30.

### Controller

The controller 80 controls the light-emitting device module 10, the heater 50, and the coil 70. The controller 80 includes a temperature control circuit 802, a wavelength control circuit 804, a light-output control circuit 806, and a high-frequency control circuit 808. The controller 80 further includes a temperature control circuit 810 and a magnetic field control circuit 812.

The temperature control circuit 802 controls the temperature control element 104 based on the measurement result of the temperature sensor 106. Thus, it is possible to adjust the temperature of the semiconductor laser 102 to a desired constant temperature, and to reduce an influence of the ambient temperature on the semiconductor laser 102. The ambient temperature is a temperature around the semiconductor laser 102, which may influence the temperature of the semiconductor laser 102.

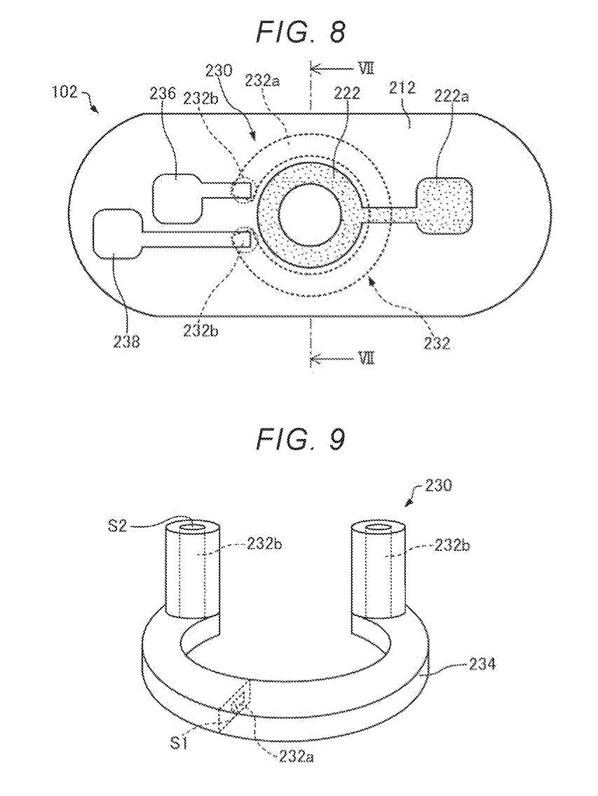

The wavelength control circuit 804 supplies a current to a third electrode 236 and a fourth electrode 238 of the semiconductor laser 102, which will be described later and are illustrated in FIG. 8, based on signal intensity of the detection signal output by the light receiving element 40. In this manner, the wavelength control circuit controls the oscillation wavelength of the semiconductor laser 102, that is, the center wavelength of the excitation light L. The wavelength control circuit 804 controls the oscillation wavelength of the semiconductor laser 102 such that the center wavelength of the excitation light L is stabilized at a wavelength corresponding the minimum signal intensity (bottom of absorption) of the detection signal of the light receiving element 40. Details of the control of the oscillation wavelength of the semiconductor laser 102 will be described later.

The light-output control circuit 806 supplies a drive current to a first electrode 220 and a second electrode 222 of the semiconductor laser 102, which will be described later and are illustrated in FIG. 7, based on the signal intensity of the detection signal output by the light receiving element 40. In this manner, the light-output control circuit controls the light output of the semiconductor laser 102. The light output means intensity of light emitted from the semiconductor laser 102 and means intensity of the light which is emitted from the semiconductor laser 102 in a state before passing through the optical members. The light-output control circuit 806 controls the semiconductor laser 102 such that the light output of the semiconductor laser 102 (light intensity of excitation light L) becomes constant. Specifically, the light-output control circuit 806 controls the light output of the semiconductor laser 102 such that the minimum value (bottom of absorption) of the signal intensity of the detection signal of the light receiving element 40 is set to a predetermined value.

The high-frequency control circuit 808 performs a control of supplying a high-frequency signal to the semiconductor laser 102. The high-frequency control circuit 808 controls the frequency of the high-frequency signal to be a frequency corresponding to the half of (ω1−ω2) of the alkali metal atom.

The temperature control circuit 810 controls energization to the heater 50 based on the measurement result of the temperature sensor 60. Thus, it is possible to maintain the atomic cell 30 to be in a desired temperature range (for example, about 70° C.)

The magnetic field control circuit 812 controls energization to the coil 70 such that the magnetic field generated by the coil 70 becomes constant.

For example, the controller 80 is provided in an integrated circuit (IC) mounted on a substrate (not illustrated).

A processor, for example, a central processing unit (CPU) may be used as the control circuits 802, 804, 806, 808, 810, and 812 constituting the controller 80. That is, the function of the controller 80 may be realized by the processor executing a program stored in a storage device (not illustrated).

### 1.2. Configuration of Light-Emitting Device Module

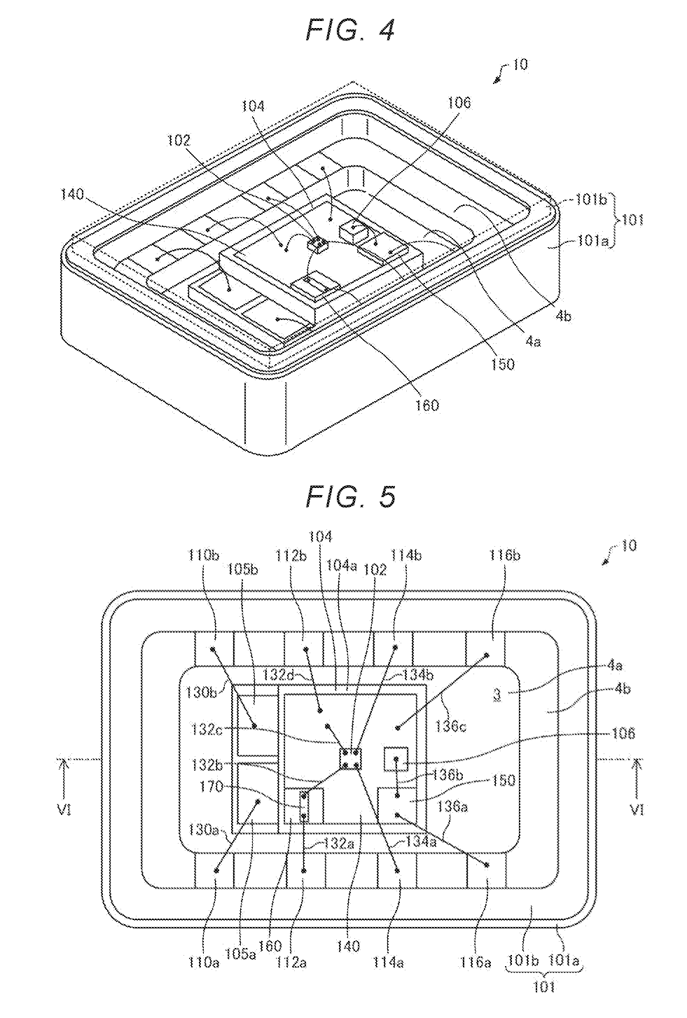

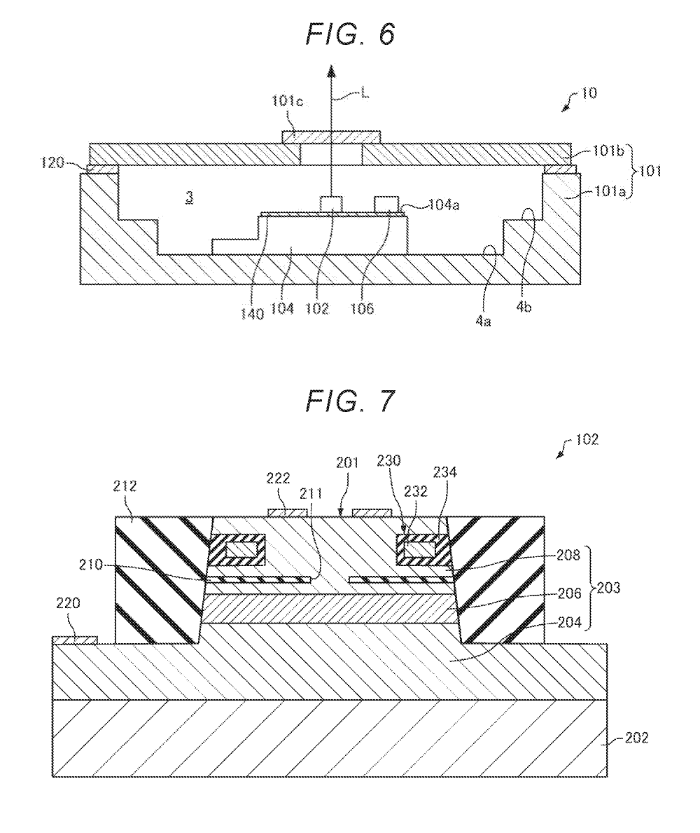

Next, a configuration of the light-emitting device module 10 will be described with reference to the drawings. FIG. 4 is a perspective view schematically illustrating the light-emitting device module 10. FIG. 5 is a plan view schematically illustrating the light-emitting device module 10. FIG. 6 is a sectional view schematically illustrating the light-emitting device module 10. FIG. 6 is a sectional view taken along line VI-VI in FIG. 5. In FIGS. 4 and 5, a lid 101b is transparently illustrated for easy descriptions.

As illustrated in FIGS. 4 to 6, the light-emitting device module 10 includes a semiconductor laser 102, a temperature control element 104, and a temperature sensor 106. The light-emitting device module 10 further includes a package 101 as a container for accommodating the semiconductor laser 102, the temperature control element 104, and the temperature sensor 106. In this specification, descriptions will be made on the assumption that, regarding a position relation in the light-emitting device module 10, relatively, the lid 101b side is set to be an upper side, and a base 101a side is set to be a lower side.

The package 101 includes the base 101a having a recess portion 3 and the lid 101b configured to close an opening of the recess portion 3. The recess portion 3 closed by the lid 101b functions as an accommodation space for accommodating the semiconductor laser 102, the temperature control element 104, and the temperature sensor 106. Preferably, the accommodation space is in a vacuum state, that is, in a state in which the pressure is lower than the atmospheric pressure. Thus, it is possible to reduce fluctuation of an external temperature of the package 101, that is, to reduce an influence of fluctuation of the ambient temperature on the semiconductor laser 102, the temperature sensor 106, or the like in the package 101. The accommodation space may not be in the vacuum state. For example, the accommodation space may be filled with an inert gas such as nitrogen, helium, and argon.

Preferably, the base 101a is formed with a material which has an insulating property and is suitable for making the accommodation space be an air-tight space. Examples of the material of the base 101a include various ceramics such as oxide ceramics (such as alumina, silica, titania, and zirconia), nitride ceramics (such as silicon nitride, aluminum nitride, and titanium nitride), and carbide ceramics (such as silicon carbide). As the material of the base 101a, a metal material similar to that of the lid 101b may be used.

The base 101a has a first surface 4a and a second surface 4b. The first surface 4a is a surface of the base 101a, which serves as the bottom surface of the recess portion 3. The second surface 4b is disposed on an upper side of the first surface 4a. In the example in FIGS. 5 and 6, the second surface 4b is an upper surface of a step portion formed in the base 101a. As illustrated in FIG. 5, a pair of connection electrodes 110a and 110b, a pair of connection electrodes 112a and 112b, a pair of connection electrodes 114a and 114b, and connection electrodes 116a and 116b are disposed on the second surface 4b. The connection electrodes 110a and 110b are electrically connected to the temperature control element 104. The connection electrodes 112a and 112b are electrically connected to the first electrode 220 and the second electrode 222 of the semiconductor laser 102, which will be described later and are illustrated in FIG. 7. The connection electrodes 114a and 114b are electrically connected to the third electrode 236 and the fourth electrode 238 of the semiconductor laser 102, which will be described later and are illustrated in FIG. 8. The connection electrodes 116a and 116b are electrically connected to the temperature sensor 106. Although not illustrated, respectively, the connection electrodes 110a, 110b, 112a, 112b, 114a, 114b, 116a, and 116b are electrically connected to external mounted electrodes (not illustrated) provided on a lower surface of the base 101a, that is, on a surface of the base 101a far from the lid 101b, via through electrodes.

The shape of the lid 101b is a flat-plate shape, for example. As illustrated in FIG. 6, a through-hole is formed in the lid 101b. The through-hole is sealed by a window member 101c having permeability for the excitation light L. The lid 101b is bonded to the base 101a with a brazing material by welding with a metallized layer 120 provided on an upper end surface of the base 101a.

The material of portions of the lid 101b other than the window member 101c is not particularly limited, and a metal material is desirably used. Among metal materials, a metal material having a linear expansion coefficient which is approximate to that of the constituent material of the base 101a is preferably used. For example, in a case where the base 101a is a ceramic substrate, an alloy such as Kovar is preferably used as the material of the lid 101b.

The window member 101c is disposed on the optical path of the excitation light L emitted from the semiconductor laser 102. The shape of the window member 101c is a plate-shape in the example in FIG. 6. The window member 101c may have a bent surface in order to function as a lens.

The temperature control element 104 is disposed on the first surface 4a of the base 101a. The temperature control element 104 controls the temperature of the semiconductor laser 102. The temperature control element 104 is controlled based on the output of the temperature sensor 106 in order to reduce the influence of the ambient temperature on the semiconductor laser 102, such that the temperature of the semiconductor laser 102 is set to be a desired predetermined constant temperature.

The temperature control element 104 is a Peltier element, for example. The temperature control element 104 has a temperature control surface 104a having a temperature to be controlled. In the temperature control element 104, the temperature control surface 104a may be set as a surface for heating (heating surface), and the temperature control surface 104a may be set as a surface for absorption (absorption surface). The semiconductor laser 102 and the temperature sensor 106 are disposed on the temperature control surface 104a. The temperature of the temperature control surface 104a can be appropriately set in accordance with characteristics of the semiconductor laser 102. A metal layer 140 formed of, for example, metal such as aluminum, gold, and silver, which has excellent thermal conductivity is disposed on the temperature control surface 104a.

The temperature control element 104 has a pair of terminals 105a and 105b. The terminal 105a is electrically connected to the connection electrode 110a via a wiring 130a. The terminal 105b is electrically connected to the connection electrode 110b via a wiring 130b. Thus, the temperature control element 104 can be driven by supplying a current from an external mounted electrode to the pair of terminals 105a and 105b. The wirings 130a and 130b are bonding wires, for example.

The temperature sensor 106 is disposed on the temperature control surface 104a of the temperature control element 104. In the example in FIG. 6, the temperature sensor 106 is disposed on the temperature control surface 104a via the metal layer 140. Although not illustrated, the temperature sensor 106 may be directly disposed on the temperature control surface 104a. The temperature sensor 106 measures the temperature of the temperature control element 104 or the semiconductor laser 102. For example, a thermistor and a thermocouple may be used as the temperature sensor 106.

Although not illustrated, the temperature sensor 106 has a pair of terminals. One terminal of the pair of terminals is a terminal for the detection signal. The other terminal is a terminal for ground. As illustrated in FIG. 5, the terminal for the detection signal is electrically connected to the connection electrode 116a via a wiring 136b, a wiring layer (not illustrated) provided in the relay member 150, and a wiring 136a. The terminal for ground is electrically connected to the connection electrode 116b via the metal layer 140 and a wiring 136c. The wirings 136a, 136b, and 136c are bonding wires, for example.

The relay member 150 has an insulating property. The material of the relay member 150 is ceramics, for example. The wiring layer provided in the relay member 150 is interposed in the middle of a wiring that connects the temperature sensor 106 and the connection electrode 116a to each other, that is, interposed between the wiring 136a and the wiring 136b. Thus, the wirings 136a and 136b can be thermally connected to the temperature control surface 104a of the temperature control element 104, and thus to reduce the temperature fluctuation of the wirings 136a and 136b.

The semiconductor laser 102 is disposed on the temperature control surface 104a of the temperature control element 104. In the example in FIG. 6, the semiconductor laser 102 is disposed on the temperature control surface 104a via the metal layer 140. Although not illustrated, the semiconductor laser 102 may be directly disposed on the temperature control surface 104a. In the example in FIG. 6, the semiconductor laser 102 and the temperature sensor 106 are disposed on the same metal layer 140. Therefore, it is possible to transfer heat to the semiconductor laser 102 and the temperature sensor 106 with high efficiency and to reduce a temperature difference between the semiconductor laser 102 and the temperature sensor 106.

For example, the semiconductor laser 102 is a vertical cavity surface emitting laser (VCSEL). The semiconductor laser 102 emits the first resonant light L1 and the second resonant light L2 described above, as the excitation light L by using the resultant of superimposing a high-frequency signal on a DC bias current.

The semiconductor laser 102 includes the first electrode 220 and the second electrode 222 which will be described later and are illustrated in FIG. 7. The first electrode 220 is electrically connected to the connection electrode 112a via a wiring 132b, a wiring layer 170 provided in a relay member 160, and a wiring 132a. The second electrode 222 is electrically connected to the connection electrode 112b via a wiring 132c, the metal layer 140, and a wiring 132d. Thus, the semiconductor laser 102 can be driven by supplying the drive current to the first electrode 220 and the second electrode 222 from an external mounted electrode.

The relay member 160 has an insulating property. The material of the relay member 160 is ceramics, for example. The wiring layer 170 provided in the relay member 160 is interposed in the middle of a wiring that connects the semiconductor laser 102 and the connection electrode 112a to each other, that is, interposed between the wiring 132a and the wiring 132b. Thus, the wirings 132a and 132b can be thermally connected to the temperature control surface 104a of the temperature control element 104, and thus to reduce the temperature fluctuation of the wirings 132a and 132b.

The semiconductor laser 102 has the third electrode 236 and the fourth electrode 238 which will be described later and are illustrated in FIG. 8. The third electrode 236 is electrically connected to the connection electrode 114a via a wiring 134a. The fourth electrode 238 is electrically connected to the connection electrode 114b via a wiring 134b. Thus, it is possible to control the oscillation wavelength of the semiconductor laser 102 by supplying a current to the third electrode 236 and the fourth electrode 238 from an external mounted electrode. The wirings 132a, 132b, 132c, 132d, 134a, and 134b are bonding wires, for example.

Although not illustrated, a connection between the third electrode 236 and the connection electrode 114a and a connection between the fourth electrode 238 and the connection electrode 114b may be made via the wiring layer provided in the relay member or the metal layer 140, similar to the connection between the electrode 220 and the connection electrode 112a and the connection between the electrode 222 and the connection electrode 112b.

### 1.3. Configuration of Semiconductor Laser

Next, a configuration of the semiconductor laser 102 will be described with reference to the drawings. FIG. 7 is a sectional view schematically illustrating the semiconductor laser 102. FIG. 8 is a plan view schematically illustrating the semiconductor laser 102. FIG. 9 is a perspective view schematically illustrating a heater element 230 of the semiconductor laser 102. FIG. 7 is a sectional view taken along line VII-VII in FIG. 8. In FIG. 8, illustrations of members other than an insulation layer 212, the second electrode 222, and the heater element 230 are omitted for easy descriptions. In this specification, descriptions will be made on the assumption that, regarding a position relation in the semiconductor laser 102, relatively, the second electrode 222 side is set to be an upper side, and a substrate 202 side is set to be a lower side.

As illustrated in FIGS. 7 and 8, the semiconductor laser 102 includes the substrate 202, a first mirror layer 204, an active layer 206, a second mirror layer 208, a current confinement layer 210 which has an opening 211 and functions as an insulation layer, the insulation layer 212, the first electrode 220, the second electrode 222, and the heater element 230.

The substrate 202 is a GaAs substrate of a first conductive type (for example, n-type), for example. The substrate 202 is disposed on the temperature control surface 104a of the temperature control element 104.

The first mirror layer 204 is disposed on the substrate 202. The first mirror layer 204 is disposed on the substrate 202 side with respect to the active layer 206. For example, the first mirror layer 204 is an n-type semiconductor layer. The first mirror layer 204 is a distributed Bragg reflector (DBR) mirror. The first mirror layer 204 is configured in a manner that a high-refractive index layer and a low-refractive index layer are alternately stacked. The high-refractive index layer is, for example, an n-type Al0.12Ga0.88As layer in which silicon has been doped. The low-refractive index layer is, for example, an n-type Al0.9Ga0.1As layer in which silicon has been doped. The number (number of pairs) of stacked high-refractive index layers and low-refractive index layers is from 10 pairs to 50 pairs, for example.

The active layer 206 is disposed on the first mirror layer 204. The active layer 206 is disposed between the first mirror layer 204 and the second mirror layer 208. For example, the active layer 206 has a multi-quantum well (MQW) structure in which three quantum well structures are stacked. The quantum well structure is configured with an i-type In0.06Ga0.94As layer and an i-type Al0.3Ga0.7As layer.

The second mirror layer 208 is disposed on the active layer 206. The second mirror layer 208 is disposed on an opposite side of the substrate 202 with respect to the active layer 206. The second mirror layer 208 is a semiconductor layer of a second conductive type (for example, p-type), for example. The second mirror layer 208 is a distributed Bragg reflector (DBR) mirror. The second mirror layer 208 is configured in a manner that a high-refractive index layer and a low-refractive index layer are alternately stacked. The high-refractive index layer is, for example, a p-type Al0.12Ga0.88As layer in which carbon has been doped. The low-refractive index layer is, for example, a p-type Al0.9Ga0.1As layer in which carbon has been doped. The number (number of pairs) of stacked high-refractive index layers and low-refractive index layers is from 3 pairs to 40 pairs, for example.

The second mirror layer 208, the active layer 206, and the first mirror layer 204 constitute a resonator 203. The second mirror layer 208, the active layer 206, and the first mirror layer 204 constitute a pin diode of a vertical resonator type. If a voltage is applied between the electrodes 220 and 222 in a forward direction of the pin diode, electrons and holes in the active layer 206 are recombined, and thus light is emitted. Light emitted in the active layer 206 reciprocates (is multiply reflected) between the first mirror layer 204 and the second mirror layer 208. Stimulated emission occurs at this time, and thus the intensity is amplified. If an optical gain exceeds an optical loss, laser oscillation is caused, and thereby laser light is emitted from an upper surface of the second mirror layer 208.

The active layer 206, the second mirror layer 208, and the current confinement layer 210 constitute a columnar portion 201. The columnar portion 201 is surrounded by the insulation layer 212. For example, the columnar portion 201 is disposed on the first mirror layer 204 and protrudes upward from the first mirror layer 204.

The current confinement layer 210 is disposed between the first mirror layer 204 and the second mirror layer 208. For example, the current confinement layer 210 may be disposed on the active layer 206 or may be disposed in the second mirror layer 208. The current confinement layer 210 is, for example, a layer obtained by oxidizing a AlxGal-xAs layer (x≥0.95). The current confinement layer 210 has the opening 211 functioning as a current path. With the current confinement layer 210, it is possible to prevent an occurrence of a situation in which a current flowing into the active layer 206 spreads in-plane in the active layer 206.

The insulation layer 212 is disposed in the resonator 203. In the example illustrated in FIG. 7, the insulation layer 212 is disposed on a side surface of the columnar portion 201 and an upper surface of the first mirror layer 204. For example, in plan view of the first mirror layer 204 (hereinafter, “in plan view”), the insulation layer 212 surrounds the columnar portion 201. The insulation layer 212 is, for example, a polyimide layer.

The first electrode 220 is connected to the first mirror layer 204. The first electrode 220 is electrically connected to the first mirror layer 204. The first electrode 220 is disposed on the first mirror layer 204. The first electrode 220 is disposed in a region of the first mirror layer 204 except for a region in which the columnar portion 201 has been formed and a region in which the insulation layer 212 has been disposed. The first electrode 220 may be disposed on a contact layer (not illustrated) disposed on the first mirror layer 204. That is, the first electrode 220 may be connected to the first mirror layer 204 via the contact layer. For example, a stacked layer obtained by stacking a Cr layer, a Pt layer, a Ti layer, a Pt layer, and an Au layer from the first mirror layer 204 side in this order is used as the first electrode 220. The first electrode 220 is one electrode for causing a current to flow into the active layer 206. The wiring 132b illustrated in FIG. 5 is connected to the first electrode 220.

The second electrode 222 is connected to the second mirror layer 208. The second electrode 222 is electrically connected to the second mirror layer 208. The second electrode 222 is disposed on the second mirror layer 208. The second electrode 222 may be disposed on a contact layer (not illustrated) disposed on the second mirror layer 208. That is, the second electrode 222 may be connected to the second mirror layer 208 via the contact layer. For example, a stacked layer obtained by stacking a Cr layer, a Pt layer, a Ti layer, a Pt layer, and an Au layer from the second mirror layer 208 side in this order is used as the second electrode 222. The second electrode 222 is the other electrode for causing the current to flow into the active layer 206.

The wiring 132c illustrated in FIG. 5 is connected to the second electrode 222. In the example illustrated in FIG. 8, a pad 222a connected to the second electrode 222 is provided on the insulation layer 212. The second electrode 222 and the wiring 132c are electrically connected to each other via the pad 222a.

As illustrated in FIGS. 7 to 9, the heater element 230 includes a semiconductor layer 232, an insulation region 234, the third electrode 236, and the fourth electrode 238.

The semiconductor layer 232 is disposed in the second mirror layer 208. The semiconductor layer 232 is surrounded by the insulation region 234. The material of the semiconductor layer 232 is the same as the material of the second mirror layer 208. The semiconductor layer 232 has a first portion 232a and a second portion 232b . The first portion 232a is in an in-plane with the second mirror layer 208. The second portion 232b overlaps the first portion 232a in plan view. In the example in FIGS. 7 to 9, the first portion 232a and the second portion 232b are orthogonal to each other.

The first portion 232a is a ring shape in plan view. More specifically, the first portion 232a has a shape in which a portion of a ring has been cut out, in plan view. The first portion 232a is disposed to surround the opening 211 of the current confinement layer 210, n plan view. Thus, it is possible to uniformly change the temperature of the resonator 203. The first portion 232a is a portion that connects one of two second portions 232b to the other thereof.

The two second portions 232b are provided. In the example in FIGS. 8 and 9, the two second portions 232b are connected to both ends of the first portion 232a, respectively. The one of the two second portions 232b connects the first portion 232a and the third electrode 236 to each other. The other of the two second portions 232b connects the first portion 232a and the fourth electrode 238 to each other. The one of the two second portions 232b is a portion that connects the third electrode 236 to the first portion 232a. The other of the two second portions 232b is a portion that connects the fourth electrode 238 to the first portion 232a. The second portion 232b functions as a wiring for supplying a current to the first portion 232a.

The second portions 232b may not be provided in the semiconductor layer 232. For example, although not illustrated, a through electrode connected to the first portion 232a of the semiconductor layer 232 may be provided instead of the second portion 232b. The through electrode may be formed, for example, in a manner that the second mirror layer 208 has been etched, and then is buried with a metal material.

The insulation region 234 insulates the second mirror layer 208 and the semiconductor layer 232 from each other. As will be described later, the insulation region 234 is a region in which crystal defects are made in a manner that protons are implanted into a semiconductor layer constituting the second mirror layer 208 by an electric field acceleration. The insulation region 234 is disposed in the second mirror layer 208. The insulation region 234 is located over the active layer 206, that is, located on the second electrode 222 side with respect to the active layer 206. Thus, it is possible to reduce a possibility of an occurrence of defects in the active layer 206 by implanting protons when the insulation region 234 is formed.

The insulation region 234 does not overlap the opening 211 of the current confinement layer 210 in plan view. That is, the insulation region 234 is disposed to avoid a path of light in the resonator 203. Therefore, it is possible to reduce output fluctuation of light, which occurs by the light passing through the insulation region 234, in the resonator 203. In the example in FIGS. 7 to 9, the insulation region 234 overlaps only an oxidized region of the current confinement layer 210 (that is, a region other than the opening 211), in plan view.

The third electrode 236 is connected to the semiconductor layer 232. The third electrode 236 is electrically connected to the semiconductor layer 232. The third electrode 236 is connected to the one of the two second portions 232b. The third electrode 236 is one electrode for supplying a current to the semiconductor layer 232.

The fourth electrode 238 is connected to the semiconductor layer 232. The fourth electrode 238 is electrically connected to the semiconductor layer 232. The fourth electrode 238 is connected to the other of the two second portions 232b. The fourth electrode 238 is the other electrode for supplying the current to the semiconductor layer 232.

The third electrode 236 and the fourth electrode 238 are disposed on the second mirror layer 208 and the insulation layer 212. The materials of the third electrode 236 and the fourth electrode 238 are the same as the material of the second electrode 222, for example.

In the heater element 230, in a case where the current flowing in the semiconductor layer 232 is set as I, a voltage applied to the semiconductor layer 232 is set as V, and resistance of the semiconductor layer 232 is set as R, an expression of I×V=I2×R is satisfied. Here, the resistance R is proportional to (1/sectional area of the semiconductor layer). For example, the sectional area S1 of the first portion 232a along the second portion 232b is constant. In the example in FIG. 9, the sectional area S1 of the first portion 232a along the second portion 232b is a sectional area of the first portion 232a orthogonal to the second mirror layer 208. It is possible to uniformly heat the resonator 203 by setting the sectional area S1 of the first portion 232a along the second portion 232b to be constant.

The sectional area S2 of the second portion 232b along the first portion 232a is larger than the sectional area S1 of the first portion 232a along the second portion 232b. In the example in FIG. 9, the sectional area S2 of the second portion 232b along the first portion 232a is a sectional area of the second portion 232b orthogonal to the second mirror layer 208. It is possible to reduce heat generated in the second portion 232b by setting the sectional area S2 of the second portion 232b to be larger than the sectional area S1 of the first portion 232a.

In the heater element 230, if a current is supplied from the third electrode 236 and the fourth electrode 238 to the semiconductor layer 232, the semiconductor layer 232 generates heat, and thus the resonator 203 can be heated or cooled. For example, it is also possible to lower the temperature of the resonator 203 by the heater element 230, that is, to cool the resonator 203 in a manner that the temperature of the heater element 230 is controlled based on a temperature which is higher than the temperature of the temperature control surface 104a of the temperature control element 104.

In the semiconductor laser 102, the oscillation wavelength changes by heating or cooling the resonator 203. Here, in a case where the refractive index of the resonator 203 is set as n, and the length of the resonator is set as Lc, the oscillation wavelength λ can be obtained by an expression of λ=n×Lc. In addition to the refractive index n and the length Lc of the resonator, if the temperature of the resonator 203 is changed, the oscillation wavelength λ also changes because of temperature dependency. For example, if the temperature of the resonator 203 is changed by 1° C., the oscillation wavelength λ changes by about 60 pm.

As described above, in the semiconductor laser 102, it is possible to control the oscillation wavelength of the semiconductor laser 102 by controlling the temperature of the resonator 203 with the heater element 230. In the atomic oscillator 100, the temperature of the resonator 203 is controlled by using the heater element 230, for example, with accuracy of about several mK.

Here, in the atomic oscillator 100, preferably, the temperature of the semiconductor laser 102 is controlled at a high speed such that a feedback control for stabilizing the center wavelength of the excitation light L, which will be described later, to be a wavelength corresponding to the bottom of absorption. In other words, preferably, the temperature of the semiconductor laser 102 is changed at a high speed.

In the semiconductor laser 102, the semiconductor layer 232 of the heater element 230 is disposed in the second mirror layer 208. Thus, it is possible to control the temperature of the resonator 203 at a high speed, for example, in comparison to a case where the resonator 203 is heated or cooled from the outside of the semiconductor laser 102. Thus, it is possible to easily realize the feedback control for stabilizing the center wavelength of the excitation light L to be the wavelength corresponding to the bottom of absorption.

The above descriptions are made on the assumption that the AlGaAs-based surface emitting laser is provided as the semiconductor laser 102. However, a surface emitting laser using a semiconductor material of a GaInP type, a ZnSSe type, an InGaN type, an AlGaN type, an InGaAs type, a GaInNAs type, and a GaAsSb type may be provided as the semiconductor laser 102.

### 1.4. Method of Manufacturing Semiconductor Laser

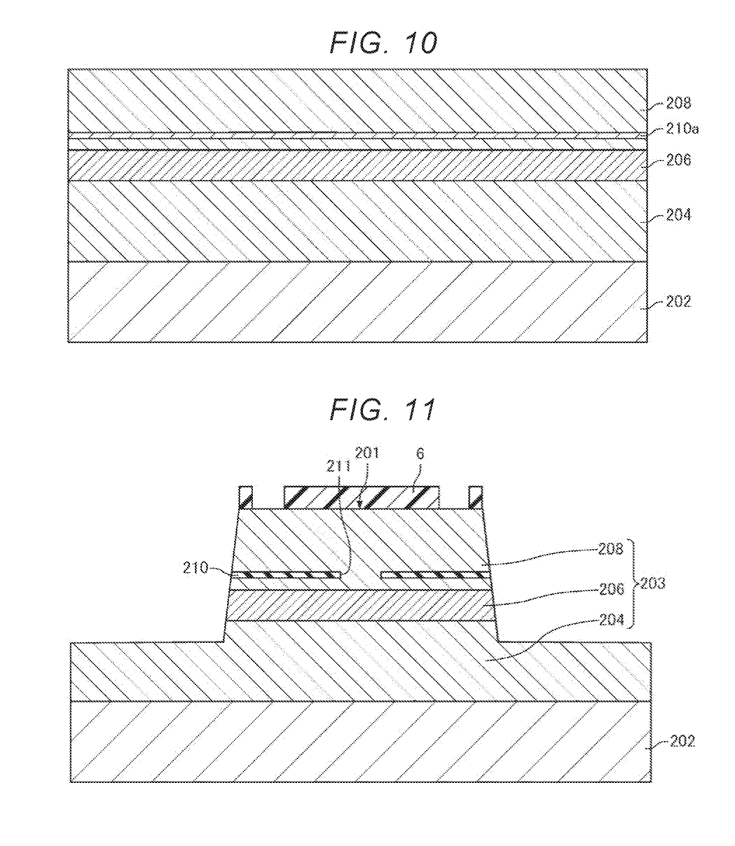

Next, a method of manufacturing the semiconductor laser 102 will be described. FIGS. 10 to 14 are sectional views schematically illustrating a step of manufacturing the semiconductor laser 102, according to the embodiment.

As illustrated in FIG. 10, a first mirror layer 204, an active layer 206, a second mirror layer 208, and an oxidization target layer 210a are formed on a substrate 202 in a manner of epitaxial growth. The oxidization target layer 210a is oxidized so as to serve as a current confinement layer 210. Examples of a method for the epitaxial growth include a metal organic chemical vapor deposition (MOCVD) method and a molecular beam epitaxy (MBE) method.

Then, as illustrated in FIG. 11, the second mirror layer 208, the oxidization target layer 210a, the active layer 206, and the first mirror layer 204 are patterned, and thereby the columnar portion 201 is formed. The layers are patterned, for example, by photolithography and etching. Then, the oxidization target layer 210a is oxidized from a side surface of the oxidization target layer 210a, and thereby the current confinement layer 210 having an opening 211 is formed.

Then, a proton shielding layer 6 having a predetermined shape is formed on the second mirror layer 208. The proton shielding layer 6 is a resist layer, for example.

As illustrated in FIG. 12, protons are implanted into the second mirror layer 208 up to a predetermined depth by using the proton shielding layer 6 as a mask. Thus, an insulation region 234 in which crystal defects have been formed can be formed at a stop position of protons. Then, the proton shielding layer 6 is removed. In the example illustrated in FIG. 12, a portion of the insulation region 234 illustrated in FIG. 7, which covers the lower side of the semiconductor layer 232 is formed. The implantation depth of protons, that is, the stop position of the protons can be controlled by energy in implantation of protons, that is, kinetic energy of the protons. The resistance value of the insulation region 234 can be controlled by the amount of implanted protons. Here, a case of implanting protons is described. However, ions other than protons may be implanted.

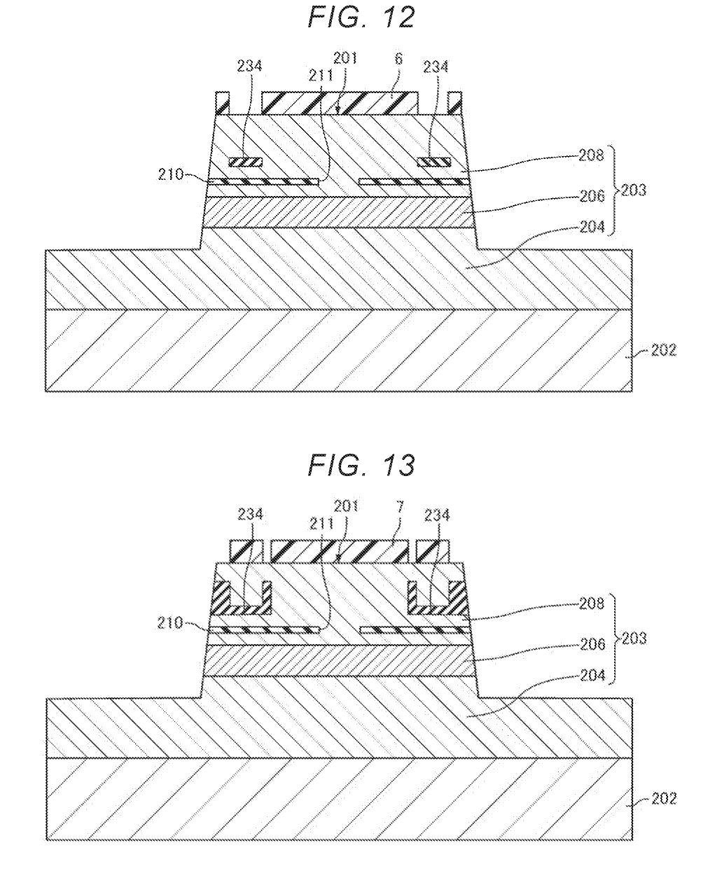

Then, as illustrated in FIG. 13, a proton shielding layer 7 having a shape which is different from that of the proton shielding layer 6 is formed on the second mirror layer 208. Protons are implanted into the second mirror layer 208 up to a predetermined depth by using the proton shielding layer 7 as a mask. Then, the proton shielding layer 7 is removed. In the example illustrated in FIG. 13, a portion of the insulation region 234 illustrated in FIG. 7, which covers the side of the semiconductor layer 232 is formed.

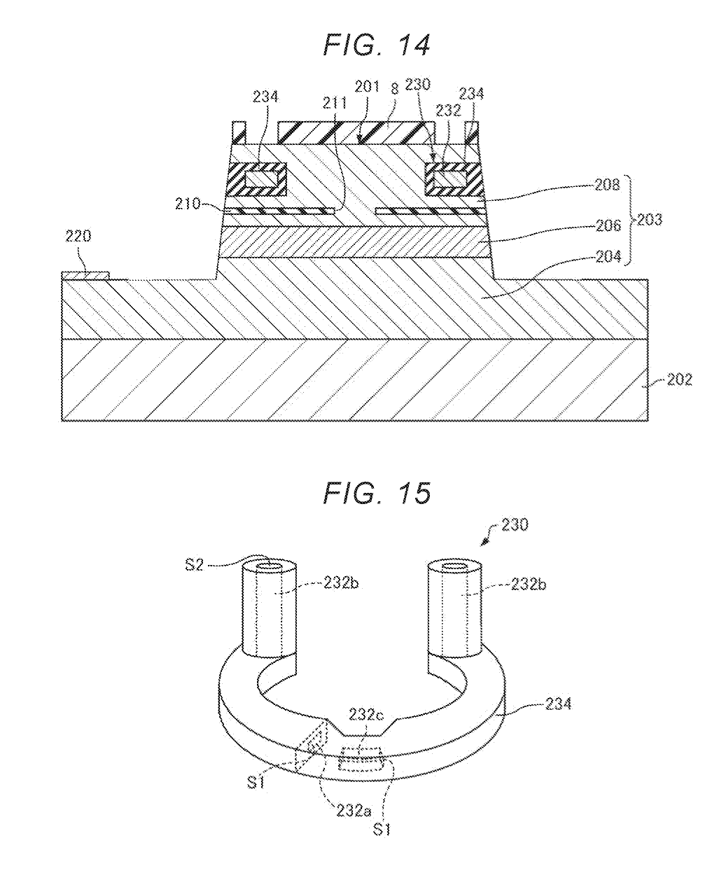

Similarly, as illustrated in FIG. 14, a proton shielding layer 8 is formed. For example, the shape of the proton shielding layer 8 is the same as the shape of the proton shielding layer 6. Protons are implanted into the second mirror layer 208 up to a predetermined depth by using the proton shielding layer 8 as a mask. At this time, the implantation depth of protons is set to be shallower than that in the case illustrated in FIG. 12. Then, the proton shielding layer 8 is removed. In the example illustrated in FIG. 14, a portion of the insulation region 234 illustrated in FIG. 7, which covers the upper side of the semiconductor layer 232 is formed.

As described above, the insulation region 234 having a desired shape and the semiconductor layer 232 having a desired shape can be formed by repeating implantation of protons.

Then, as illustrated in FIG. 7, an insulation layer 212 is formed in order to cover the side surface of the columnar portion 201. The insulation layer 212 is formed, for example, by a spin coating method.

Then, as illustrated in FIG. 7, a first electrode 220 is formed on the first mirror layer 204. As illustrated in FIGS. 7 and 8, a second electrode 222 is formed on the second mirror layer 208. As illustrated in FIG. 8, a third electrode 236 and a fourth electrode 238 are formed on the second mirror layer 208 and the insulation layer 212. The electrodes 220, 222, 236, and 238 are formed, for example, by a vacuum deposition method. An order of forming the electrodes 220, 222, 236, and 238 is not particularly limited.

With the above steps, the semiconductor laser 102 can be manufactured.

In the above descriptions, a case where the columnar portion 201 is formed, and then the insulation region 234 is formed is described. However, the insulation region 234 may be formed, and then the columnar portion 201 may be formed.

### 1.5. Operation of Atomic Oscillator

Next, an operation of the atomic oscillator 100 will be described. Firstly, an initial operation when the stopped atomic oscillator 100 is activated will be described.

The light-output control circuit 806 changes the light output of the semiconductor laser 102 based on the signal intensity of a detection signal output by the light receiving element 40. Specifically, the light-output control circuit 806 changes the light output of the semiconductor laser 102 such that the minimum value (bottom of absorption) of the signal intensity of the detection signal when the center wavelength of the excitation light L varies becomes a predetermined value.

Then, the high-frequency control circuit 808 inputs a high-frequency signal to the semiconductor laser 102. At this time, the frequency of the high-frequency signal is slightly shifted such that the EIT phenomenon does not occur. For example, in a case where cesium is used as the alkali metal atom in the atomic cell 30, the frequency of the high-frequency signal is shifted from 4.596 GHz.

Then, the wavelength control circuit 804 sweeps the center wavelength of the excitation light L. At this time, since the frequency of the high-frequency signal is set to an extent that the EIT phenomenon does not occur, the EIT phenomenon does not occur. The wavelength control circuit 804 detects the minimum value (bottom of absorption) of the signal intensity of the detection signal output from the light receiving element 40 when the center wavelength of the excitation light L is swept. For example, the wavelength control circuit 804 sets a value of when the change of the signal intensity of the detection signal is equal to or less than a predetermined ratio with respect to the center wavelength of the excitation light L, as the bottom of absorption.

If the bottom of absorption is detected, the wavelength control circuit 804 fixes (locks) the center wavelength of the excitation light L. That is, the wavelength control circuit 804 fixes the center wavelength of the excitation light L to be a wavelength corresponding to the bottom of absorption.

Then, the high-frequency control circuit 808 adjusts the frequency of the high-frequency signal to be a frequency at which the EIT phenomenon occurs. Then, a loop operation is performed, and thereby, the high-frequency control circuit 808 detects an EIT signal by synchronously detecting the detection signal output by the light receiving element 40.

Next, a loop operation of the atomic oscillator 100 will be described.

The high-frequency control circuit 808 detects the EIT signal by synchronously detecting the detection signal output by the light receiving element 40 and controls the frequency of the high-frequency signal to be a frequency corresponding to the half of (ω1−ω2) of the alkali metal atom in the atomic cell 30.

The wavelength control circuit 804 performs a feedback control for stabilizing the center wavelength of the excitation light L to be the wavelength corresponding to the bottom of absorption. Specifically, the wavelength control circuit 804 synchronously detects the detection signal output by the light receiving element 40 and controls the heater element 230 so as to set the center wavelength of the excitation light L to be the wavelength corresponding to the bottom of absorption.

The light-output control circuit 806 performs a feedback control to cause the light output of the semiconductor laser 102 to be constant. For example, the light-output control circuit 806 synchronously detects the detection signal output by the light receiving element 40. In a case where the minimum value (bottom of absorption) of the signal intensity of the detection signal is smaller than a predetermined value, the light-output control circuit supplies a drive current to the semiconductor laser 102 so as to set the minimum value (bottom of absorption) of the signal intensity of the detection signal to reach the predetermined value. Even though the center wavelength of the excitation light L is shifted from the wavelength corresponding to the bottom of absorption by the control of the light-output control circuit 806, it is possible to match the center wavelength of the excitation light L with the wavelength of the bottom of absorption by the control of the wavelength control circuit 804.

### 1.6. Effects

The semiconductor laser 102 has effects as follows, for example.

The semiconductor laser 102 includes the semiconductor layer 232 disposed in the second mirror layer 208, the insulation region 234 that insulates the second mirror layer 208 and the semiconductor layer 232 from each other, and the third electrode 236 and the fourth electrode 238 connected to the semiconductor layer 232. Therefore, in the semiconductor laser 102, it is possible to heat or cool the resonator 203 in a manner that heat is generated by supplying a current to the semiconductor layer 232. Thus, in the semiconductor laser 102, it is possible to control the temperature of the resonator 203 by using the semiconductor layer 232. Accordingly, it is possible to control the oscillation wavelength of the semiconductor laser 102.

The semiconductor laser 102 further includes the first electrode 220 connected to the first mirror layer 204 and the second electrode 222 connected to the second mirror layer 208. Therefore, in the semiconductor laser 102, it is possible to control the light output of the semiconductor laser 102 by supplying the drive current to the first electrode 220 and the second electrode 222.

Thus, in the semiconductor laser 102, it is possible to separately control the light output of the semiconductor laser 102 and the oscillation wavelength of the semiconductor laser 102. Accordingly, it is possible to reduce an occurrence of a situation in which the light output of the semiconductor laser 102 fluctuates by controlling the oscillation wavelength of the semiconductor laser 102, for example, in comparison to a case where the oscillation wavelength of the semiconductor laser 102 is controlled with the drive current.

Here, in a case where the oscillation wavelength of the semiconductor laser 102 is caused to fluctuate at the temperature of the resonator 203, the degree of fluctuation of the light output of the semiconductor laser 102 is much smaller than, for example, that in a case where the oscillation wavelength of the semiconductor laser 102 is caused to fluctuate by the drive current. Therefore, it is possible to reduce the occurrence of a situation in which the light output of the semiconductor laser 102 fluctuates by controlling the oscillation wavelength of the semiconductor laser 102, by controlling the oscillation wavelength of the semiconductor laser 102 at the temperature of the resonator 203.

In the semiconductor laser 102, since the semiconductor layer 232 is disposed in the second mirror layer 208, it is possible to directly supply heat to the resonator 203 and to change the temperature of the resonator 203 at a high speed. Thus, in the semiconductor laser 102, it is possible to control the oscillation wavelength of the semiconductor laser 102 at a high speed.

In the semiconductor laser 102, since the semiconductor layer 232 is disposed in the second mirror layer 208, it is possible to reduce a distance between the semiconductor layer 232 and the active layer 206, for example, in comparison to a case where the semiconductor layer 232 is disposed on the second mirror layer 208. Thus, in the semiconductor laser 102, it is possible to supply heat to the active layer 206 with high efficiency. Here, the oscillation wavelength of the semiconductor laser 102 is more sensitive to the change of the temperature of the active layer 206 than to the change of the temperatures of the first mirror layer 204 and the second mirror layer 208. Therefore, in the semiconductor laser 102, as described above, it is possible to supply heat to the active layer 206 with high efficiency. Thus, it is possible to improve control responsiveness and to reduce the consumed power.

In the semiconductor laser 102, since the semiconductor layer 232 is disposed in the second mirror layer 208, it is difficult to apply the influence of the ambient temperature to the semiconductor layer 232, for example, in comparison to a case where the semiconductor layer 232 is disposed on the second mirror layer 208. Thus, it is possible to control the temperature of the resonator 203 with high accuracy.

In the semiconductor laser 102, the second mirror layer 208 is disposed on an opposite side of the substrate 202 with respect to the active layer 206. Therefore, in the semiconductor laser 102, protons do not pass through the active layer 206 when the insulation region 234 is formed by implanting the protons. Thus, it is possible to reduce a possibility of defects occurring in the active layer 206 by implanting the protons. Accordingly, it is possible to lengthen the lifespan of the semiconductor laser 102.

The semiconductor laser 102 includes the current confinement layer 210 which has the opening 211 and functions as the insulation layer. The insulation region 234 does not overlap the opening 211 in plan view. As described above, since the insulation region 234 is disposed to avoid the path of light in the resonator 203, it is possible to reduce output fluctuation of light, which occurs by the light passing through the insulation region 234, in the resonator 203.

In the semiconductor laser 102, the semiconductor layer 232 has the first portion 232a in-plane with the second mirror layer 208 and the second portion 232b that overlaps the first portion 232a in plan view. The sectional area S2 of the second portion 232b along the first portion 232a is larger than the sectional area S1 of the first portion 232a along the second portion 232b. Therefore, it is possible to reduce heat generated in the second portion 232b.

In the semiconductor laser 102, if heat is generated in the semiconductor layer 232, the refractive index is changed by the heat in the resonator 203, and thus a lens action occurs by the change of the refractive index (thermal lens effect). A radiation angle of light emitted from the semiconductor laser 102 may be controlled by using the lens action. For example, in the example illustrated in FIG. 9, it is possible to converge light generated in the active layer 206 by using the lens action which occurs by heat being generated in the semiconductor layer 232. Thus, it is easy to maintain a single mode, for example.

In the atomic oscillator 100, for example, effects as follows are obtained.

The atomic oscillator 100 includes the semiconductor laser 102. Therefore, in the atomic oscillator 100, it is possible to separately control the oscillation wavelength of the semiconductor laser 102 and the light output of the semiconductor laser 102. Thus, it is possible to reduce the occurrence of a situation in which the light output of the semiconductor laser 102 fluctuates by controlling the oscillation wavelength of the semiconductor laser 102, for example, in comparison to a case where the oscillation wavelength of the semiconductor laser 102 is controlled with the drive current. Accordingly, in the atomic oscillator 100, it is possible to reduce light shift by fluctuation of the light output of the semiconductor laser 102 and to realize an atomic oscillator having excellent frequency stability.

Further, as described above, the semiconductor laser 102 can control the oscillation wavelength of the semiconductor laser 102 at a high speed. Thus, in the atomic oscillator 100, it is possible to easily realize a feedback control for stabilizing the center wavelength of the excitation light L to be the wavelength corresponding to the bottom of absorption.

In the atomic oscillator 100, the light output of the semiconductor laser 102 is controlled in a manner that the light-output control circuit 806 supplies a current to the first electrode 220 and the second electrode 222 of the semiconductor laser 102 based on the detection signal of the light receiving element 40. In the atomic oscillator 100, the oscillation wavelength of the semiconductor laser 102 is controlled in a manner that the wavelength control circuit 804 supplies a current to the third electrode 236 and the fourth electrode 238 of the semiconductor laser 102 based on the detection signal of the light receiving element 40. Therefore, in the atomic oscillator 100, it is possible to control the light output of the semiconductor laser 102 with the drive current of the semiconductor laser 102 and to control the oscillation wavelength of the semiconductor laser 102 at the temperature of the resonator 203.

For example, if the oscillation wavelength of the semiconductor laser 102 is controlled with the drive current of the semiconductor laser 102, the light output of the semiconductor laser 102 also fluctuates by controlling the oscillation wavelength of the semiconductor laser 102. Therefore, for example, in a case where the light output of the semiconductor laser 102 changes over time, if the drive current for bringing the light output of the semiconductor laser 102 back to an initial value is controlled, the oscillation wavelength also fluctuates. In a case where the oscillation wavelength of the semiconductor laser 102 changes over time, and a case where both the light output and the oscillation wavelength change over time, the similar problem occurs. As described above, in a case where the oscillation wavelength of the semiconductor laser 102 is controlled with the drive current of the semiconductor laser 102, compensation for the change of the light output or the oscillation wavelength of the semiconductor laser 102 for a long term is not possible. Thus, long-term stability of the atomic oscillator may be deteriorated.

On the contrary, in the atomic oscillator 100, since it is possible to separately control the oscillation wavelength of the semiconductor laser 102 and the light output of the semiconductor laser 102, the phenomenon as described above does not occur, and thus it is possible to realize an atomic oscillator having excellent long-term stability.

### 1.7. Modification Examples

Next, modification examples of the semiconductor laser 102 according to the embodiment will be described. In the modification examples described below, members having functions similar to those of the constituent members of the above-described semiconductor laser 102 are denoted by the same reference signs, and detailed descriptions thereof will not be repeated.

### 1.7.1. First Modification Example

FIG. 15 is a perspective view schematically illustrating a heater element 230 in a semiconductor laser according to a first modification example.

As illustrated in FIG. 9, in the heater element 230 of the above-described semiconductor laser 102, the sectional area S1 of the first portion 232a of the semiconductor layer 232 along the second portion 232b is constant.

On the contrary, in the heater element 230 of the semiconductor laser in the first modification example, as illustrated in FIG. 15, a constricted portion 232c is provided in the first portion 232a of the semiconductor layer 232. The constricted portion 232c has a sectional area S1 along the second portion 232b, which is smaller than those of other portions of the first portion 232a. Therefore, the amount of heat generated at the constricted portion 232c is larger than those of other portions of the first portion 232a. Thus, it is possible to partially heat the resonator 203.

### 1.7.2. Second Modification Example

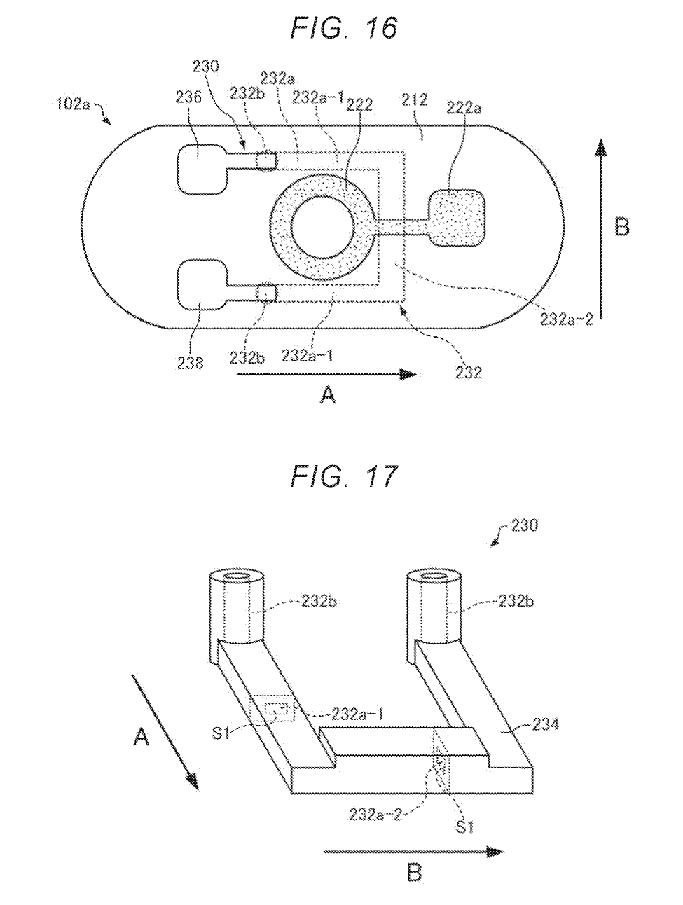

FIG. 16 is a plan view schematically illustrating a semiconductor laser 102a according to a second modification example. FIG. 17 is a perspective view schematically illustrating a heater element 230 of the semiconductor laser 102a according to the second modification example.

As illustrated in FIGS. 8 and 9, in the above-described semiconductor laser 102, the first portion 232a of the semiconductor layer 232 has a ring shape, more specifically, a shape in which a portion of a ring has been cut out, in plan view.

On the contrary, in the semiconductor laser 102a according to the second modification example, as illustrated in FIGS. 16 and 17, the first portion 232a of the semiconductor layer 232 has a rectangular frame shape, more specifically a shape in which a portion of a rectangular frame has been cut out, in plan view.

The first portion 232a of the semiconductor layer 232 has a first extension portion 232a-1 along a first direction A and a second extension portion 232a-2 along a second direction B orthogonal to the first direction A. Two first extension portions 232a-1 are provided, and are respectively connected to the second portions 232b. Two facing sides of a rectangle are constituted by the two first extension portions 232a-1. One side of the rectangle, which connects the two sides is constituted by the second extension portion 232a-2.

In the semiconductor laser 102a, since the first portion 232a of the semiconductor layer 232 has a rectangular frame shape, it is possible to make temperature distribution in the first direction A to differ from temperature distribution in the second direction B, in the resonator 203. Thus, it is possible to apply anisotropic stress to the resonator 203 and to align the polarized light of light emitted from the semiconductor laser 102a.

In the example illustrated in FIGS. 16 and 17, in the first portion 232a of the semiconductor layer 232, the sectional area S1 of the second extension portion 232a-2 along the second portion 232b is larger than the sectional area Si of the first extension portion 232a-1 along the second portion 232b. Therefore, the amount of heat generated at the second extension portion 232a-2 is smaller than the amount of heat generated at the first extension portion 232a-1. Thus, in the resonator 203, it is possible to cause the temperature distribution in the first direction A to differ from the temperature distribution in the second direction B more largely. Thus, it is possible to increase the anisotropic stress applied to the resonator 203 and to more align the polarized light of light emitted from the semiconductor laser 102a.

In the example illustrated in FIGS. 16 and 17, it is possible to control an irradiation angle of light emitted from the semiconductor laser 102 in a specific direction by using the thermal lens effect which occurs by heat being generated in the semiconductor layer 232.

### 1.7.3. Third Modification Example

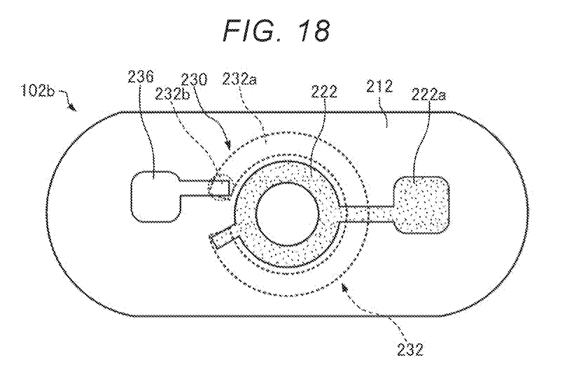

FIG. 18 is a plan view schematically illustrating a semiconductor laser 102b according to a third modification example.

As illustrated in FIG. 8, in the above-described semiconductor laser 102, the heater element 230 includes the third electrode 236 and the fourth electrode 238.

On the contrary, in the semiconductor laser 102b according to the third modification example, a heater element 230 does not include the fourth electrode 238, and the second electrode 222 is used instead of the fourth electrode 238. That is, the second electrode 222 is connected to not only the second mirror layer 208 and but also to the semiconductor layer 232. Therefore, the second electrode 222 functions as the electrode for causing the current to flow into the active layer 206 and also functions as the electrode for supplying the current to the semiconductor layer 232. Thus, in the semiconductor laser 102b, it is possible to reduce the number of components and to simplify a device.

### 1.7.4. Fourth Modification Example

As illustrated in FIG. 7, in the above-described semiconductor laser 102, the second mirror layer 208 in which the semiconductor layer 232 and the insulation region 234 have been provided is disposed on the upper portion of the active layer 206, that is, disposed on an opposite side of the substrate 202 with respect to the active layer 206. On the contrary, although not illustrated, the second mirror layer 208 in which the semiconductor layer 232 and the insulation region 234 have been provided may be disposed on the lower portion of the active layer 206, that is, disposed on the substrate 202 side with respect to the active layer 206. In this case, the first mirror layer 204 is disposed on the upper portion of the active layer 206, that is, disposed on an opposite side of the substrate 202 with respect to the active layer 206.

### 2. Frequency Signal Generation System

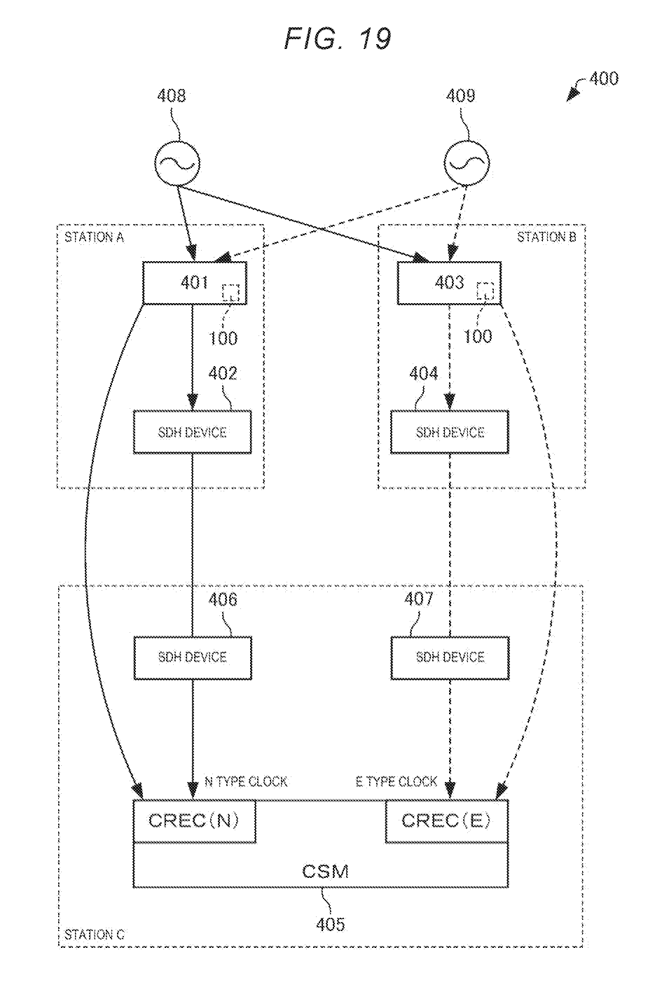

Next, a frequency signal generation system according to the embodiment will be described with reference to the drawings. A clock transmission system (timing server) as follows is an example of the frequency signal generation system. FIG. 19 is a schematic diagram illustrating a configuration of a clock transmission system 400.

The clock transmission system includes the atomic oscillator according to the embodiments. The clock transmission system 400 including the atomic oscillator 100 will be described below, as an example.

The clock transmission system 400 matches clocks of devices in a time division multiplexing network with each other. The clock transmission system 400 is a system having a redundant configuration of a normal (N) type and an emergency (E) type.

As illustrated in FIG. 19, the clock transmission system 400 includes a clock supply device 401 and a synchronous digital hierarchy (SDH) device 402 of Station A (higher (N type)), a clock supply device 403 and a SDH device 404 of Station B (higher (E type)), and a clock supply device 405 and SDH devices 406 and 407 of Station C (lower). The clock supply device 401 includes the atomic oscillator 100 and generates an N type clock signal. The atomic oscillator 100 in the clock supply device 401 synchronizes with a clock signal which has high precision and is from master clocks 408 and 409 including an atomic oscillator using cesium and generates a clock signal.

The SDH device 402 transmits and receives a main signal based on the clock signal from the clock supply device 401. In addition, the SDH device 402 superimposes an N type clock signal on the main signal and transmits the resultant of the superimposition to the lower clock supply device 405. The clock supply device 403 includes the atomic oscillator 100 and generates an E type clock signal. The atomic oscillator 100 in the clock supply device 403 synchronizes with a clock signal which has higher precision and is from the master clocks 408 and 409 including the atomic oscillator using cesium and generates a clock signal.

The SDH device 404 transmits and receives a main signal based on the clock signal from the clock supply device 403. In addition, the SDH device 404 superimposes an E type clock signal on the main signal and transmits the resultant of the superimposition to the lower clock supply device 405. The clock supply device 405 receives the clock signals from the clock supply devices 401 and 403. The clock supply device 405 synchronizes with the received clock signal and generates a clock signal.

Normally, the clock supply device 405 synchronizes with the N type clock signal from the clock supply device 401 and generates the clock signal. In a case where the N type signal has a problem, the clock supply device 405 synchronizes with the E type clock signal from the clock supply device 403 and generates the clock signal. As described above, it is possible to guarantee a stable clock supply and to improve reliability of a clock path network, by switching from the N type to the E type. The SDH device 406 transmits and receives a main signal based on the clock signal from the clock supply device 405. Similarly, the SDH device 407 transmits and receives a main signal based on the clock signal from the clock supply device 405. Thus, it is possible to cause the device of Station C to synchronize with the device of Station A or Station B.

The frequency signal generation system according to the embodiment is not limited to the clock transmission system. The frequency signal generation system includes various devices in which the atomic oscillator is mounted, and a frequency signal of the atomic oscillator is used, and a system constituted by a plurality of devices in which the atomic oscillator is mounted, and a frequency signal of the atomic oscillator is used.

Examples of the frequency signal generation system according to the embodiment may include a smartphone, a tablet terminal, a timepiece, a portable phone, a digital still camera, a liquid ejecting apparatus (for example, ink jet printer), a personal computer, a television, a video camera, a video tape recorder, a car navigation device, a pager, an electronic notebook, an electronic dictionary, a calculator, an electronic game device, a word processor, a workstation, a video phone, a television monitor for security, an electronic binocular, a point-of-sales (POS) terminal, medical equipment (for example, electronic thermometer, blood pressure monitor, blood glucose meter, electrocardiogram measuring device, ultrasonic diagnostic device, electronic endoscope, a magnetocardiogram meter), a fish finder, a global navigation satellite system (GNSS) frequency standard, various measuring devices, instruments (for example, instruments of automobiles, aircrafts, ships), a flight simulator, a terrestrial digital broadcasting system, a portable phone base station, and moving objects (automobiles, aircrafts, ships, and the like).

In the invention, some components may be omitted, or the embodiment and the modification examples maybe combined, in a range having the features and the effects described in this application.

The invention includes substantially the same configurations as the configuration described in the embodiment (for example, configuration having the same functions, methods, and results or configuration having the same object and effects. The invention includes a configuration in which not-essential parts of the configuration described in the embodiment are replaced. The invention includes a configuration which achieves the same advantageous effects as the configuration described in the embodiment or a configuration which can achieve the same object. The invention includes a configuration in which well-known technologies are added to the configuration described in the embodiment.

What is claimed is:

1. A semiconductor laser comprising:
a first mirror layer;
a second mirror layer;
an active layer disposed between the first mirror layer and the second mirror layer;
a semiconductor layer disposed in the second mirror layer;
an insulation region configured to insulate the second mirror layer and the semiconductor layer from each other;
a first electrode connected to the first mirror layer;
a second electrode connected to the second mirror layer; and
a third electrode connected to the semiconductor layer.

2. The semiconductor laser according to claim 1, further comprising:
a substrate,
wherein the active layer is disposed between the substrate and the second mirror layer.

3. The semiconductor laser according to claim 1, further comprising:
an insulation layer having an opening,
wherein the insulation region does not overlap the opening in a plan view of the second mirror layer.

4. The semiconductor laser according to claim 1,
wherein the semiconductor layer has
a first portion in-plane with the second mirror layer, and
a second portion that overlaps the first portion in a plan view of the second mirror layer, and
a sectional area of the second portion along the first portion is larger than a sectional area of the first portion along the second portion.

5. The semiconductor laser according to claim 2,
wherein the semiconductor layer has
a first portion in-plane with the second mirror layer, and
a second portion that overlaps the first portion in a plan view of the second mirror layer, and
a sectional area of the second portion along the first portion is larger than a sectional area of the first portion along the second portion.

6. The semiconductor laser according to claim 3,
wherein the semiconductor layer has
a first portion in-plane with the second mirror layer, and
a second portion that overlaps the first portion in a plan view of the second mirror layer, and
a sectional area of the second portion along the first portion is larger than a sectional area of the first portion along the second portion.

7. The semiconductor laser according to claim 1,
wherein the second electrode is connected to the semiconductor layer.

8. An atomic oscillator comprising:
a semiconductor laser including
a first mirror layer,
a second mirror layer,
an active layer disposed between the first mirror layer and the second mirror layer,
a semiconductor layer disposed in the second mirror layer,
an insulation region configured to insulate the second mirror layer and the semiconductor layer from each other,
a first electrode connected to the first mirror layer,
a second electrode connected to the second mirror layer, and
a third electrode connected to the semiconductor layer;
an atomic cell which is irradiated with light emitted from the semiconductor laser and in which an alkali metal atom is accommodated; and
a light receiving element that detects intensity of light transmitted through the atomic cell and outputs a detection signal.

9. The atomic oscillator according to claim 8, further comprising:
a light-output control circuit that controls a light output of the semiconductor laser by supplying a current to the first electrode and the second electrode of the semiconductor laser based on the detection signal; and
a wavelength control circuit that controls an oscillation wavelength of the semiconductor laser by supplying a current to the third electrode based on the detection signal.

10. A frequency signal generation system comprising:
an atomic oscillator,
wherein the atomic oscillator includes
a semiconductor laser including
a first mirror layer,
a second mirror layer,
an active layer disposed between the first mirror layer and the second mirror layer,
a semiconductor layer disposed in the second mirror layer,
an insulation region configured to insulate the second mirror layer and the semiconductor layer from each other,
a first electrode connected to the first mirror layer,
a second electrode connected to the second mirror layer, and
a third electrode connected to the semiconductor layer,
an atomic cell which is irradiated with light emitted from the semiconductor laser and in which an alkali metal atom is accommodated, and
a light receiving element that detects intensity of light transmitted through the atomic cell and outputs a detection signal.
